(19) United States
(12) Patent Application Publication
(10) Pub. No.: US 2020/0266234 A1
(43) Pub. Date: Aug. 20, 2020

(54) SYSTEMS AND METHODS FOR FABRICATION OF SUPERCONDUCTING DEVICES

(71) Applicant: D-WAVE SYSTEMS INC., Burnaby (CA)

(72) Inventors: Kelly T.R. Boothby, Coquitlam (CA); Loren J. Swenson, Burnaby (CA); Mark H. Volkmann, Burnaby (CA); Jed D. Whittaker, Vancouver (CA)

(21) Appl. No.: 16/389,669

(22) Filed: Apr. 19, 2019

Related U.S. Application Data
(60) Provisional application No. 62/660,719, filed on Apr. 20, 2018.

(51) Int. Cl. H01L 27/18; H01L 49/02; H01L 39/22; H01L 39/24; G06N 10/00

(52) U.S. Cl. CPC H01L 27/18; H01L 28/60; G06N 10/00; H01L 39/2493; H01L 39/223

(57) ABSTRACT

Apparatus and methods advantageously provide parallel-plate capacitors in superconducting integrated circuits. A method may include forming a metal-oxide layer to overlie at least a portion of a first capacitor plate, the first capacitor plate comprising a superconductive material, and depositing a second capacitor plate to overlie at least a portion of the metal-oxide layer, the second capacitor plate comprising a superconductive material. The method may include depositing a base electrode of superconductive material to overlie at least a portion of a substrate, depositing the first capacitor plate to overlie at least a portion of the base electrode, and superconductingly electrically coupled to the base electrode, and depositing a counter electrode of superconductive material to overlie at least a portion of the second capacitor plate, the counter electrode superconductingly electrically coupled to the second capacitor plate. The superconducting integrated circuit may include a parallel-plate capacitor and a Josephson junction.

### BACKGROUND

### Technical Field

This disclosure generally relates to systems and methods for fabrication of superconducting devices, and, more specifically, to systems and methods for fabrication of capacitors for use in superconducting integrated circuits.

### Frequency Multiplexed Resonant (FMR) Readout

Superconducting microwave resonators have been used in a variety of fields including, but not limited to, quantum computation and astronomy. For example, in quantum computation, superconducting resonators have been used to detect the state of qubits. In astronomy, superconducting microwave resonators have been used in Microwave Kinetic Inductance Detectors (MKIDs). In both cases, many resonators (detectors) can be coupled to a common transmission line and integrated through frequency domain multiplexing. Frequency domain multiplexing (FDM) is a technique in which a communication bandwidth is divided into a number of non-overlapping sub-bands, each sub-band used to carry a separate signal.

Using FMR technology, superconducting resonators of different resonant frequencies can be used for readout of multiple qubits. The resonators can share a common microwave transmission line by using frequency domain multiplexing.

### Parallel-Plate Capacitors

Capacitors can be basic building blocks for superconducting integrated circuits. For example, capacitors can be components of resonators used in integrated circuits operable to perform frequency-multiplexed resonant input/output to a superconducting device.

One type of capacitor is a parallel-plate capacitor, in which a dielectric is sandwiched between two capacitor plates. Each capacitor plate can be electrically coupled to an electrode. One of the electrodes is referred to in the present application as a base electrode and the other is referred to as a counter electrode. The capacitance C of a parallel plate capacitor can be expressed as:

$$C = \frac{ϵ A}{d}$$

where ϵ is the permittivity of the dielectric separating the plates, A is the area of one of the plates and d is the thickness of the dielectric.

A superconducting parallel plate thin-film capacitor can be integrated in a heterogeneous multi-layer planarized fabrication stack with deposited dielectrics. See for example PCT Patent Application No. WO2016US31885 (published as International patent application publication WO2016183213A1) entitled “Frequency Multiplexed Resonator Input and/or Output for a Superconducting Device”.

### BRIEF SUMMARY

A method of fabricating a parallel-plate capacitor in a superconducting integrated circuit may be summarized as including: forming a metal-oxide layer to overlie at least a portion of a first capacitor plate, the first capacitor plate comprising a material that is superconductive in a range of temperatures; depositing a second capacitor plate to overlie at least a portion of the metal-oxide layer, the second capacitor plate comprising a material that is superconductive in a range of temperatures; depositing a base electrode to overlie at least a portion of a substrate, the base electrode comprising a material that is superconductive in a range of temperatures; depositing the first capacitor plate to overlie at least a portion of the base electrode, the first capacitor plate superconductingly electrically coupled to the base electrode; and depositing a counter electrode to overlie at least a portion of the second capacitor plate, the counter electrode comprising a material that is superconductive in a range of temperatures, wherein the counter electrode is superconductingly electrically coupled to the second capacitor plate.

Depositing a base electrode to overlie at least a portion of a substrate may include depositing a base electrode by at least one of physical vapor deposition and chemical vapor deposition. Depositing a base electrode to overlie at least a portion of a substrate may include depositing a base electrode to overlie a substrate that comprises silicon. Depositing a base electrode to overlie at least a portion of a substrate may include depositing a superconducting metal layer that comprises at least one of niobium and aluminum. Depositing a counter electrode to overlie at least a portion of the second capacitor plate may include depositing a counter electrode by at least one of physical vapor deposition and chemical vapor deposition. Depositing a counter electrode to overlie at least a portion of the second capacitor plate may include depositing a counter electrode that comprises a superconducting trace. Depositing a counter electrode to overlie at least a portion of a substrate may include depositing a superconducting metal layer that comprises at least one of niobium and aluminum.

The method of fabricating a parallel-plate capacitor in a superconducting integrated circuit may further include patterning the first capacitor plate, the metal-oxide layer, and the second capacitor plate.

Patterning the first capacitor plate, the metal-oxide layer, and the second capacitor plate may include performing a photolithographic process that comprises masking and etching the first capacitor plate, the metal-oxide layer, and the second capacitor plate to remove at least a respective portion of each of the first capacitor plate, the metal-oxide layer, and the second capacitor plate. Depositing a counter electrode to overlie at least a portion of the second capacitor plate may include: depositing a dielectric layer to overlie at least a portion of the second capacitor plate and at least a portion of an exposed surface of the base electrode; removing at least a portion of the dielectric layer to form a hole exposing at least a portion of the second capacitor plate; and depositing a superconducting metal layer to at least partially fill the hole. Depositing a dielectric layer to overlie at least a portion of the second capacitor plate may include depositing a dielectric layer that comprises silicon dioxide. Depositing a dielectric layer to overlie at least a portion of the second capacitor plate may include planarizing the dielectric layer.

The method of fabricating a parallel-plate capacitor in a superconducting integrated circuit may further include planarizing at least one of the base electrode, the first capacitor plate, the second capacitor plate, and the counter electrode.

Forming a metal-oxide layer to overlie at least a portion of the first capacitor plate may include depositing a metal-oxide layer to overlie at least a portion of the first capacitor plate. Depositing a metal-oxide layer to overlie at least a portion of the first capacitor plate may include depositing a metal-oxide layer by at least one of physical vapor deposition and chemical vapor deposition. Depositing a metal-oxide layer to overlie at least a portion of the first capacitor plate may include depositing a metal-oxide layer that comprises at least one of niobium oxide and aluminum oxide. Forming a metal-oxide layer to overlie at least a portion of the first capacitor plate may include depositing a metal layer to overlie at least a portion of the first capacitor plate and oxidizing an exposed surface of the metal layer, the metal layer superconductive in a range of temperatures. Depositing a metal layer to overlie at least a portion of the first capacitor plate may include depositing a metal layer by at least one of physical vapor deposition and chemical vapor deposition. Depositing a metal layer to overlie at least a portion of the first capacitor plate may include depositing a metal layer that comprises at least one of niobium and aluminum. Oxidizing an exposed surface of the metal layer may include exposing an exposed surface of the metal layer to oxygen gas (O2). A thickness of the first capacitor plate may be in the range of 20 nm to 500 nm, a thickness of the metal-oxide layer may be in the range of 2 nm to 20 nm, and a thickness of the second capacitor plate may be in the range of 20 nm to 500 nm.

A superconducting integrated circuit may be summarized as including: a substrate; a base electrode overlying at least a portion of the substrate, the base electrode superconductive in a range of temperatures; a parallel-plate capacitor overlying at least a portion of the base electrode, the parallel-plate capacitor comprising: a first capacitor plate that is superconductive in a range of temperatures; a metal-oxide layer overlying the first capacitor plate; a second capacitor plate overlying the metal-oxide layer, the second capacitor plate superconductive in a range of temperatures, wherein the base electrode is superconductingly electrically coupled to the first capacitor plate.

The superconducting integrated circuit may further include a superconducting metal layer overlying at least a portion of the first capacitor plate, wherein the metal-oxide layer includes a native metal oxide of the superconducting metal layer.

The superconducting integrated circuit may further include: a dielectric layer overlying at least a portion of the parallel-plate capacitor and at least an exposed portion of the base electrode; a hole in the dielectric layer that exposes at least a portion of the second capacitor plate; and a superconducting metal layer overlying at least a portion of the dielectric and at least a portion of the second capacitor plate, the superconducting metal layer which forms a superconducting via and a counter electrode, wherein the counter electrode is superconductingly electrically coupled to the second capacitor plate.

A quantum processor may include the superconducting integrated circuit discussed above.

A control circuit for a quantum processor may include the superconducting integrated circuit discussed above.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not necessarily drawn to scale, and some of these elements are arbitrarily enlarged and positioned to improve drawing legibility. Further, the particular shapes of the elements as drawn, are not necessarily intended to convey any information regarding the actual shape of the particular elements, and have been solely selected for ease of recognition in the drawings.

FIG. 1A is a flowchart illustrating a method for fabricating a portion of a superconducting integrated circuit, in accordance with the present systems and methods.

FIG. 1B is a flowchart illustrating another method for fabricating a portion of a superconducting integrated circuit, in accordance with the present systems and methods.

FIGS. 2A to 2H are sectional views of a portion of an exemplary superconducting integrated circuit which includes a thin-film parallel-plate capacitor, at various stages of its fabrication, in accordance with the present systems and methods.

FIG. 3 is a schematic diagram illustrating an example implementation of a superconducting circuit comprising a superconducting resonator.

FIG. 4 is a schematic diagram of an exemplary hybrid computing system, including a digital computer and a quantum computer, that may incorporate superconducting technology as described herein.

FIG. 5 is a schematic diagram illustrating an example implementation of a readout system for a superconducting circuit.

FIG. 6 is a sectional view of a portion of an exemplary superconducting integrated circuit which includes a parallel-plate capacitor and a Josephson junction, in accordance with the present systems and methods.

### DETAILED DESCRIPTION

### Preamble

In the following description, some specific details are included to provide a thorough understanding of various disclosed embodiments. One skilled in the relevant art, however, will recognize that embodiments may be practiced without one or more of these specific details, or with other methods, components, materials, etc. In other instances, well-known structures associated with superconductive devices and integrated superconductive circuits have not been shown or described in detail to avoid unnecessarily obscuring descriptions of the embodiments of the present methods. Throughout this specification and the appended claims, the words “element” and “elements” are used to encompass, but are not limited to, all such structures, systems, and devices associated with superconductive circuits and integrated superconductive circuits.

Unless the context requires otherwise, throughout the specification and claims which follow, the word “comprise” is synonymous with “including,” and is inclusive or open-ended (i.e., does not exclude additional, unrecited elements or acts).

Reference throughout this specification to “one embodiment” “an embodiment”, “another embodiment”, “one example”, “an example”, “another example”, “one implementation”, “another implementation”, or the like means that a particular referent feature, structure, or characteristic described in connection with the embodiment, example, or implementation is included in at least one embodiment, example, or implementation. Thus, the appearances of the phrases “in one embodiment”, “in an embodiment”, “another embodiment” or the like in various places throughout this specification are not necessarily all referring to the same embodiment, example, or implementation. Furthermore, the particular features, structures, or characteristics may be combined in any suitable manner in one or more embodiments, examples, or implementations.

It should be noted that, as used in this specification and the appended claims, the singular forms “a,” “an,” and “the” include plural referents unless the content clearly dictates otherwise. Thus, for example, reference to a readout system including “a superconducting resonator” includes a single superconducting resonator, or two or more superconducting resonators. It should also be noted that the term “or” is generally employed in its sense including “and/or” unless the content clearly dictates otherwise.

The headings provided herein are for convenience only and do not interpret the scope or meaning of the embodiments.

Conventionally, capacitors are fabricated using an amorphous inter-layer dielectric (also referred to in the present application as an insulator). A shortcoming of existing systems and methods for fabricating lumped element capacitors for superconducting integrated circuits is that they can yield capacitors with a relatively large footprint. The relatively large footprint of conventional thin-film capacitors may limit where such capacitors can be used in practice.

The footprint of a thin-film parallel plate capacitor can be proportional to a ratio of the thickness of the dielectric to the relative permittivity of the dielectric. In practice, there can be restrictions on the how high the relative permittivity of the dielectric can be, and how thin the dielectric can be fabricated. Conventionally, the relative permittivity of the dielectric is typically less than approximately 10, and the thickness of the dielectric is typically greater than approximately 50 nm.

Another shortcoming of conventional approaches is that the fabrication can be vulnerable to variations and defects.

The systems and methods for fabricating thin-film capacitors described in the present application use a trilayer structure that includes a metal/metal-oxide/metal sandwich. Trilayer fabrication is known in, for example, the fabrication of a Josephson junction. See, for example, PCT Patent Application No. WO2010US025403 (published as International patent application publication WO2010099312A2), “Systems and Methods for Fabrication of Superconducting Integrated Circuits”. A photolithographic process used to define a feature of a Josephson junction can be transferable, for example, to trilayer fabrication of a thin-film parallel-plate capacitor.

The systems and methods described in the present application use a trilayer fabrication process that yields an insulating metal-oxide layer of the trilayer such that there are essentially no tunneling currents.

An advantage of the systems and methods described in the present application is that the metal oxide layer can be very thin, for example only a few nm (nanometers). Another advantage is that the relative permittivity of the metal-oxide layer can be as high or higher than the relative permittivity of an amorphous inter-layer dielectric. For example, the relative permittivity of niobium oxide is approximately 40, and the relative permittivity of aluminum oxide is approximately 10.

In some implementations of the systems and methods described in the present application, the metal-oxide layer is formed by oxidation of a superconducting metal such as niobium or aluminum or another suitable metal that can form a native oxide. In the present application, a superconducting metal is defined as a metal that can be superconducting below a characteristic critical temperature. In some implementations, the metal-oxide layer is formed by oxidation of a normal metal. In the present application, a normal metal is defined as a metal that cannot superconduct or has a characteristic critical temperature below a temperature at which the systems of the present application are typically operated.

An advantage of the systems and methods described in the present application is: a) the high relative permittivity of the metal-oxide dielectric, and b) the ability to form a reliably thin layer of the metal-oxide dielectric—which, in combination, can yield capacitors with a smaller physical footprint in an integrated circuit, for example, than conventional fabrication technology. The systems and methods described in the present application can include integration of a trilayer process to form thin-film metal-oxide capacitors with the fabrication of superconducting thin-film circuits in a scalable fabrication process for superconducting integrated circuits.

An advantage of a thin-film parallel-plate capacitor with a smaller footprint on a superconducting integrated circuit is that it can facilitate the fabrication of smaller resonators. The smaller resonators can, for example, be used in integrated circuits operable to perform frequency-multiplexed resonant input/output to a superconducting device at a greater scale than possible with resonators fabricated using conventional technology. See for example International PCT Patent Application No. WO2016US31885 (published as International patent application publication WO2016183213A1) entitled “Frequency Multiplexed Resonator Input and/or Output for a Superconducting Device”. The systems and methods described in the present application can be used to fabricate capacitors for resonators integrated with other control circuitry in a superconducting processor, such as a superconducting quantum processor.

The systems and methods described in the present application can be used to fabricate capacitors used to tune a response of a distributed circuit where a desired response may not be readily achieved using capacitors fabricating using conventional technology. High-quality capacitors that include a high-quality metal-oxide, and that are fabricated using the systems and methods described in the present application, can be used in a qubit-coupler assembly in a superconducting quantum processor, for example. The high-quality capacitors can be used to control a tunneling rate and/or a non-stoquastic coupling. See, for example, U.S. Provisional Patent Application No. 62/608501, “Systems And Methods For Coupling Qubits In A Quantum Processor”, filed Dec. 20, 2017; and PCT Patent Application No. US2018/066613, “Systems and Methods for Coupling Qubits in a Quantum Processor”, filed Dec. 19, 2018.

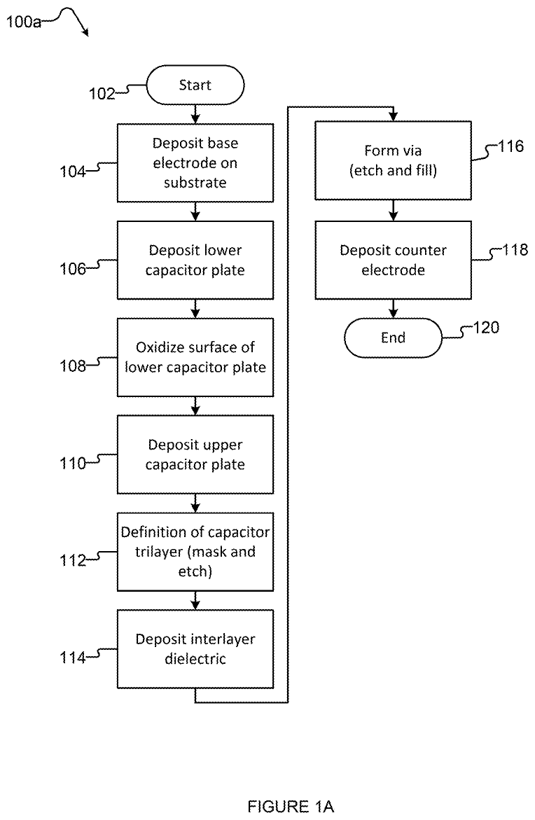

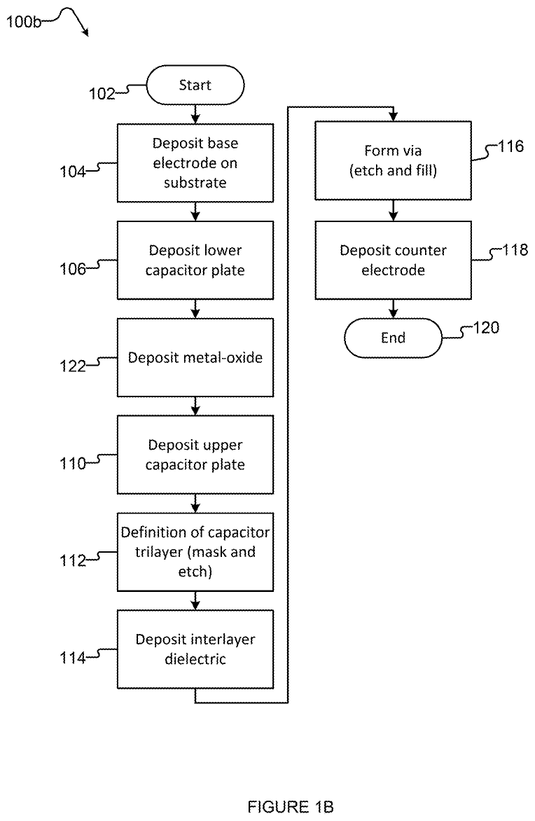

FIG. 1A is a flowchart illustrating a method 100a for fabricating a portion of a superconducting integrated circuit, in accordance with the present systems and methods. Method 100a includes acts 102-120, though those of skill in the art will appreciate that in alternative embodiments certain acts may be omitted and/or additional acts may be added. Those of skill in the art will appreciate that the illustrated order of the acts is shown for exemplary purposes only and may change in alterative embodiments.

Method 100a starts at 102, for example in response to an initiation of a fabrication process. At 104, a base electrode is deposited to overlie at least a portion of a substrate. In one implementation, the substrate is silicon. In one implementation, the base electrode is a first superconducting metal layer that is superconducting in a range of temperatures. In one implementation, the base electrode includes niobium. In one implementation, the base electrode includes aluminum.

At 106, a lower capacitor plate is deposited to overlie at least a portion of the base electrode. In one implementation, the lower capacitor plate includes a second superconducting metal layer that is superconducting in a range of temperatures. The second superconducting metal layer can be deposited using a standard deposition process such as chemical vapor deposition (CVD), or physical vapor deposition (PVD), or another suitable deposition process. In one implementation, the second superconducting metal layer includes niobium. In one implementation, the second superconducting metal layer has a thickness of approximately 150 nm.

In some implementations, it is preferred that the upper surface of the second superconducting metal layer (the surface facing away from the base electrode) be smooth and substantially uniform. If a desired smoothness and/or uniformity cannot be achieved during deposition, the upper surface of the second superconducting metal layer can be planarized and/or polished, for example by using a mechanical planarization process and/or a chemical-mechanical planarization process (CMP).

In one implementation, the lower capacitor plate includes a third superconducting metal layer that overlies the second superconducting metal layer and is superconducting in a range of temperatures. In one implementation, the third superconducting metal layer includes aluminum. In one implementation, the thickness of the third superconducting metal layer is at least an order of magnitude thinner than the thickness of the second superconducting metal layer. In the present application, an order of magnitude of a number is the smallest integer power of 10 that can be used to represent the number. In one implementation, the third superconducting metal layer has a thickness of approximately 8 nm.

At 108, the third superconducting metal layer is exposed to oxygen (O₂) gas to form a layer of metal oxide on an upper surface of the third superconducting metal layer (the upper surface is a surface facing away from the second superconducting metal layer). The metal oxide can form an insulating layer.

It can be desirable for the metal oxide formed by oxidation of the third superconducting layer to have a substantially uniform desired thickness. The thickness of the metal oxide layer can be determined by several factors including, for example, a duration of exposure to O₂ gas, a concentration of O₂ gas, a temperature, and a pressure. In practice, one approach to producing a desired metal oxide thickness is to estimate a suitable duration of exposure given an O₂ concentration in a chamber where the oxidation takes place, and the pressure and temperature in the chamber.

A benefit of the systems and methods in the present application is that the thickness of the insulating layer of the parallel-plate capacitor (i.e., the metal-oxide layer) can be accurately controlled in the oxidation process by controlling the duration of exposure to O₂ gas. Another benefit of the systems and methods in the present application is that the thickness of the insulating layer can be more uniform across a wafer that includes one or more superconducting integrated circuits.

In some implementations, O₂ gas is combined with argon gas. An advantage of using an argon/O₂ gas mixture is that oxidation can be more uniform across a wafer.

In another implementation (not illustrated in FIG. 1A), a metal oxide is deposited to overlie at least a portion of the second superconducting layer. The metal oxide can be aluminum oxide, for example. The metal oxide can be deposited using atomic layer deposition, for example. By depositing the metal oxide (for example by using atomic layer deposition), the thickness of the metal oxide layer can be controlled. In some instances, depositing the metal oxide provides greater control over the thickness of the metal oxide layer than an oxidation process (such as the oxidation process described above in the present application).

In some implementations, adhesion of the metal oxide layer to the second superconducting metal layer can be improved by first depositing a thin metal layer (such as a layer of aluminum) to overlie at least a portion of the upper surface of the second superconducting metal layer, and then depositing the metal oxide via atomic layer deposition over the thin metal layer.

At 110, an upper capacitor plate is deposited to overlie at least a portion of the metal oxide.

At 112, the capacitor trilayer (comprising the lower capacitor plate, the metal oxide insulating layer, and the upper capacitor plate) is patterned by masking and etching at least a portion of the capacitor trilayer. The capacitor trilayer may be patterned by, for example, a lithographic photoresist-masking and plasma-etching process to form individual thin-film capacitors. During the patterning of the upper capacitor plate, a metal oxide layer may be used as an etch-stop layer, and the superconducting metal of the upper capacitor plate may be etched using a chemistry that does not etch through the metal-oxide layer.

In one implementation, a thickness of the lower capacitor plate is in the range of 20 nm to 500 nm, a thickness of the metal-oxide layer is in the range of 2 nm to 20 nm, and a thickness of the second capacitor plate is in the range of 20 nm to 500 nm.

At 114, a dielectric layer is deposited to overlie the capacitor and at least a portion of the substrate that extends beyond the boundaries of the capacitor. The dielectric layer is also referred to in the present application as an interlayer dielectric. In some implementations, the interlayer dielectric is a high-loss dielectric. In some implementations, the interlayer dielectric is silicon dioxide (SiO2). In some implementations, the interlayer dielectric is planarized and/or polished, for example using chemical mechanical planarization (CMP). In one implementation, a thickness of the interlayer dielectric is approximately 200 nm.

At 116, one or more holes are etched in the interlayer dielectric exposing at least a portion of the upper capacitor plate. The one or more holes in the interlayer dielectric can be at least partially filled with superconducting metal to form one or more superconducting vias (see 118 below). In the present application, a via (vertical interconnect access) is an electrical connection between layers in a physical electronic circuit (e.g. an integrated circuit) that goes through the plane of one or more adjacent layers. The vias can be used, for example, to superconductingly electrically couple the capacitor to a superconducting trace overlying the interlayer dielectric.

At 118, a superconducting metal layer is deposited to a) form vias by at least partially filling the one or more holes in the interlayer dielectric, and b) to form a counter electrode overlying at least one of the vias. In one implementation, the counter electrode comprises a superconducting metal layer that is superconducting in a range of temperatures. In one implementation, the superconducting metal layer includes at least one superconducting trace. In one implementation, the counter electrode includes niobium. In one implementation, the counter electrode includes aluminum.

In one implementation, rather than depositing an upper capacitor plate to overlie at least a portion of the metal-oxide, a via is made through the interlayer dielectric to an exposed surface of the metal-oxide.

Method 100a concludes at 120.

FIG. 1B is a flowchart illustrating a method 100b for fabricating a portion of a superconducting integrated circuit, in accordance with the present systems and methods. Method 100b includes acts 102-106 and 110-122, though those of skill in the art will appreciate that in alternative embodiments certain acts may be omitted and/or additional acts may be added. Those of skill in the art will appreciate that the illustrated order of the acts is shown for exemplary purposes only and may change in alterative embodiments.

Method 100b includes acts 102-106 and 110-120 of FIG. 1A. A description of acts 102-106 and 110-120 is provided in the above description of FIG. 1A. Act 108 of FIG. 1A has been replaced in method 100b by act 122. At act 122, a metal-oxide layer is deposited to overlie at least a portion of the lower capacitor plate. In some implementations, the metal-oxide layer is deposited by a sputtering process. In the present application, depositing a metal-oxide layer by a sputtering process includes depositing a metal-oxide layer on a surface by using energetic particles of a plasma or a gas to eject particles of the metal-oxide from a target.

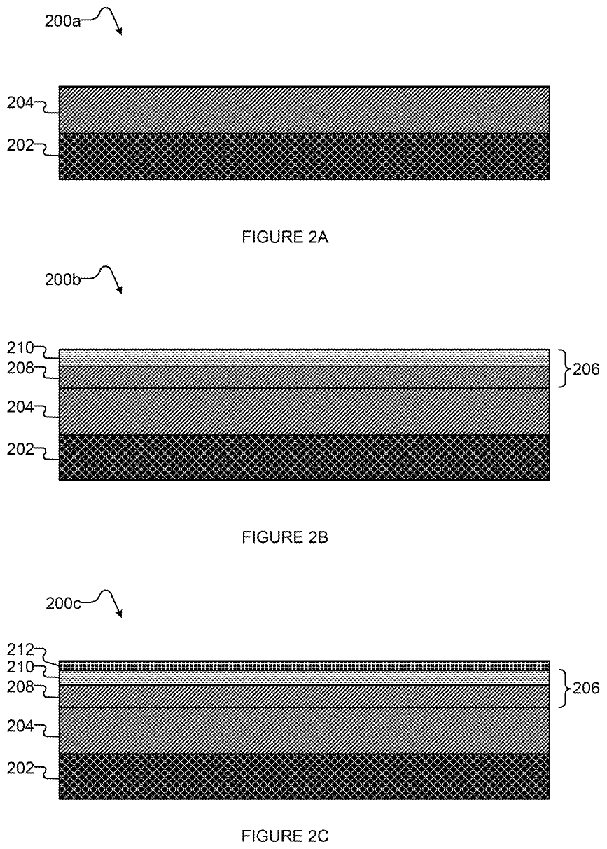

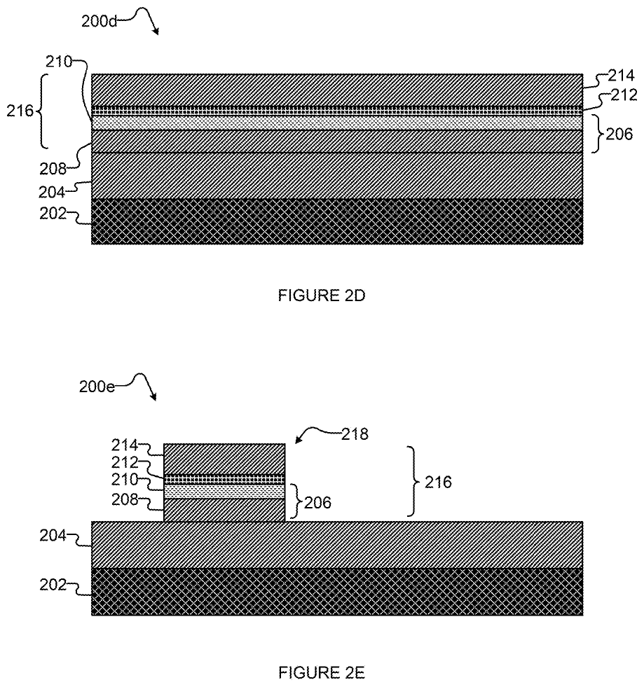

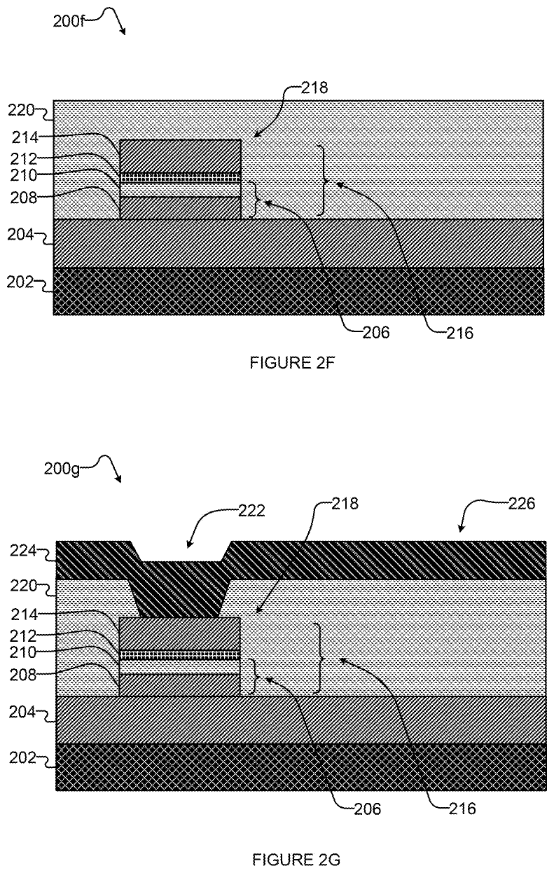

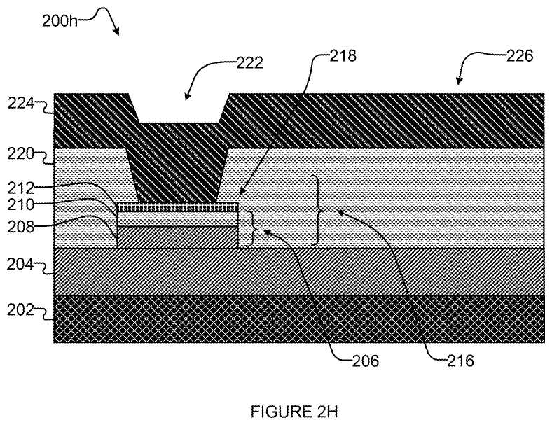

FIGS. 2A to 2H are sectional views of a portion of an exemplary superconducting integrated circuit which includes a thin-film parallel-plate capacitor, at various stages of its fabrication, in accordance with the present systems and methods.

FIG. 2A is a sectional view of a portion of a superconducting integrated circuit 200a at a first stage of a fabrication process described by method 100a of FIG. 1A. Circuit 200a includes a substrate 202 and a base electrode 204 overlying at least a portion of substrate 202. Substrate 202 may comprise or include silicon in combination with one or more other materials, or may consist of silicon or consist essentially of silicon.

In some implementations, base electrode 204 is a first superconducting metal layer.

The first superconducting metal layer of base electrode 204 may comprise or include niobium in combination with one or more other materials, or may consist of niobium or consist essentially of niobium. The first superconducting metal layer of base electrode 204 may comprise or include aluminum in combination with one or more other materials, or may consist of aluminum or consist essentially of aluminum.

In some implementations, base electrode 204 is at least part of a wiring layer.

FIG. 2B is a sectional view of a portion of a superconducting integrated circuit 200b at a subsequent stage of the fabrication process described by methods 100a of FIG. 1A and 100b of FIG. 1B. Circuit 200b can be formed from circuit 200a of FIG. 2A by depositing a lower capacitor plate 206 to overlie at least a portion of base electrode 204. In some implementations, depositing lower capacitor plate 206 includes depositing a second superconducting metal layer 208 and a third superconducting metal layer 210.

Second superconducting metal layer 208 may comprise or include niobium in combination with one or more other materials, or may consist of niobium or consist essentially of niobium. Third superconducting metal layer 210 may comprise or include aluminum in combination with one or more other materials, or may consist of aluminum or consist essentially of aluminum.

In some implementations, lower capacitor plate 206 is deposited using a standard deposition process such as chemical vapor deposition (CVD), or physical vapor deposition (PVD), or another suitable deposition process.

In some implementations, base electrode 204 and lower capacitor plate 206 are provided by a single superconducting metal layer.

FIG. 2C is a sectional view of a portion of a superconducting integrated circuit 200c at a subsequent stage of the fabrication process described by methods 100a of FIG. 1A and 100b of FIG. 1B. Circuit 200c can be formed from circuit 200b by oxidizing at least a portion of an upper surface of lower capacitor plate 206 to form a metal oxide layer 212. In some implementations, metal oxide layer 212 is formed by oxidation of third superconducting metal layer 210. In some implementations, circuit 200c is formed from circuit 200b by depositing a metal-oxide on at least a portion of an upper surface of lower capacitor plate 206 to form metal oxide layer 212.

FIG. 2D is a sectional view of a portion of a superconducting integrated circuit 200d at a subsequent stage of the fabrication process described by methods 100a of FIG. 1A and 100b of FIG. 1B. Circuit 200d can be formed from circuit 200c by depositing an upper capacitor plate 214 to overlie at least a portion of metal oxide layer 212. In some implementations, upper capacitor plate 214 is a fourth superconducting metal layer.

The fourth superconducting metal layer of upper capacitor plate 214 may comprise or include niobium in combination with one or more other materials, or may consist of niobium or consist essentially of niobium. The fourth superconducting metal layer of upper capacitor plate 214 may comprise or include aluminum in combination with one or more other materials, or may consist of aluminum or consist essentially of aluminum.

In some implementations, upper capacitor plate 214 is deposited using a standard deposition process such as chemical vapor deposition (CVD), or physical vapor deposition (PVD), or another suitable deposition process.

Lower capacitor plate 206, metal oxide layer 212, and upper capacitor plate 214 can form a capacitor trilayer 216.

FIG. 2E is a sectional view of a portion of a superconducting integrated circuit 200e at a subsequent stage of the fabrication process described by methods 100a of FIG. 1A and 100b of FIG. 1B. Circuit 200e can be formed from circuit 200d by patterning capacitor trilayer 216 to form capacitor 218. Patterning of capacitor trilayer 216 to form capacitor 218 can include masking and etching at least a portion of capacitor trilayer 216. Patterning of capacitor trilayer 216 to form capacitor 218 can include more than one masking and etching activity. Patterning of capacitor trilayer to form capacitor 218 can include masking and etching upper capacitor plate 214, metal oxide layer 212, and lower capacitor plate 206.

FIG. 2F is a sectional view of a portion of a superconducting integrated circuit 200f at a subsequent stage of the fabrication process described by methods 100a of FIG. 1A and 100b of FIG. 1B. Circuit 200f can be formed from circuit 200e by depositing a dielectric layer 220 to overlie capacitor 218 and at least a portion of base electrode 204. Dielectric layer 220 may comprise or include silicon dioxide in combination with one or more other materials, or may consist of silicon dioxide or consist essentially of silicon dioxide. In some implementations, dielectric layer 220 is planarized and/or polished, for example by a CMP process. In some implementations, dielectric layer 220 is an interlayer dielectric.

FIG. 2G is a sectional view of a portion of a superconducting integrated circuit 200g at a subsequent stage of the fabrication process described by methods 100a of FIG. 1A and 100b of FIG. 1B. Circuit 200g can be formed from circuit 200f by forming a via 222 in dielectric layer 220 (for example, by etching and filling a hole in dielectric layer 220). Forming via 222 in dielectric layer 220 can include depositing a counter electrode 224 to at least partially fill a hole etched in dielectric layer 220. Counter electrode 224 can be deposited to overlie at least a portion of dielectric layer 220. In some implementations, counter electrode 224 is a fifth superconducting metal layer. In some implementations, counter electrode 224 is part of a wiring layer.

In some implementations, counter electrode 224 includes a trace 226. In some implementations, trace 226 is a superconducting trace. In some implementations, trace 226 is at least part of a wiring layer.

Counter electrode 224 may comprise or include niobium in combination with one or more other materials, or may consist of niobium or consist essentially of niobium. Counter electrode 224 may comprise or include aluminum in combination with one or more other materials, or may consist of aluminum or consist essentially of aluminum.

In some implementations, counter electrode 224 is deposited using a standard deposition process such as chemical vapor deposition (CVD), or physical vapor deposition (PVD), or another suitable deposition process.

In some implementations, capacitor 218 is fabricated between two wiring layers in a fabrication stack of a superconducting integrated circuit.

A benefit of the systems and methods described in the present application can be a thinner parallel-plate capacitor, and a thinner interlayer dielectric.

In one implementation, at least one of the base electrode, the first capacitor plate, the second capacitor plate, and the counter electrode is planarized and/or polished.

FIG. 2H is a sectional view of a portion of another superconducting circuit 200h. Superconducting circuit 200h includes the same elements as superconducting circuit 200g of FIG. 2G except that a) second capacitor plate 214 of FIG. 2G is omitted from capacitor 218 of FIG. 2H, and b) via 222 and counter electrode 224 are directly superconductingly electrically coupled to metal-oxide layer 212. In some implementations, fabrication of superconducting circuit 200h includes forming metal-oxide layer 212 before depositing interlayer dielectric 220. In some implementations, fabrication of superconducting circuit 200h includes forming metal-oxide layer 212 after: a) depositing interlayer dielectric 220 and b) forming a hole through interlayer dielectric 220 to expose at least a portion of lower capacitor plate 206.

Superconducting Resonator with Two SQUID Loops

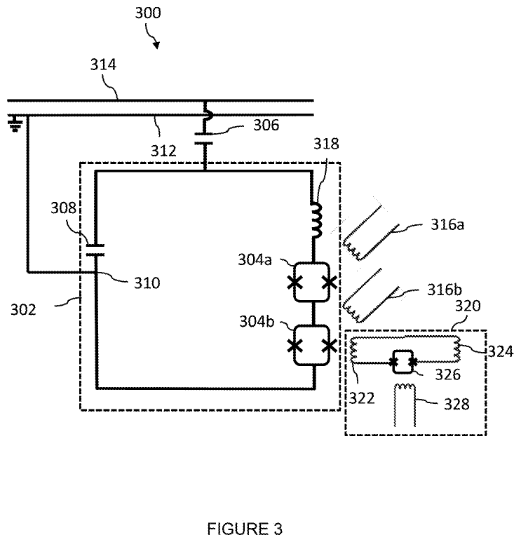

FIG. 3 shows a superconducting circuit 300 according to at least one implementation, comprising a superconducting resonator 302 with two SQUID loops, able to independently tune a resonant frequency and a sensitivity of superconducting resonator 302. Superconducting resonator 302 comprises two SQUID loops 304a and 304b. Each of SQUID loops 304a and 304b is a DC SQUID and comprises a pair of Josephson junctions in parallel with one another in a superconducting loop. SQUID loops 304a and 304b advantageously enable independent tuning of the resonance frequency and the sensitivity of superconducting resonator 302 by adjusting the flux bias in SQUID loops 304a and 304b as explained below.

Superconducting circuit 300 comprises coupling capacitance 306, and superconducting resonator 302 comprises capacitance 308. Capacitance 308 of superconducting resonator 302 can be a parallel-plate capacitor. The parallel-plate capacitor of capacitance 308 can be fabricated according to the systems and methods described in the present application.

Superconducting resonator 302 is connected at node 310 to ground, for example to the ground 312 of transmission line 314.

Interfaces 316a and 316b can provide flux bias to SQUID loops 304a and 304b respectively. Once a suitable operating point has been found (see below), the flux biases provided by interfaces 316a and 316b can be static. This advantageously allows the circuit to use an array of flux DACs requiring only a few wires to program. The two tunable SQUID loops 304a and 304b do not need an independent analog control line for each superconducting resonator 302.

Superconducting resonator 302 comprises inductor 318.

Superconducting circuit 300 comprises a last or final shift register stage 320. Last shift register stage 320 comprises inductances 322 and 324, SQUID loop 326 and interface 328. Last or final shift register stage 320 may, for example, take the form of a Quantum Flux Parametron (QFP).

### FMR Technology for Readout of Superconducting Qubits

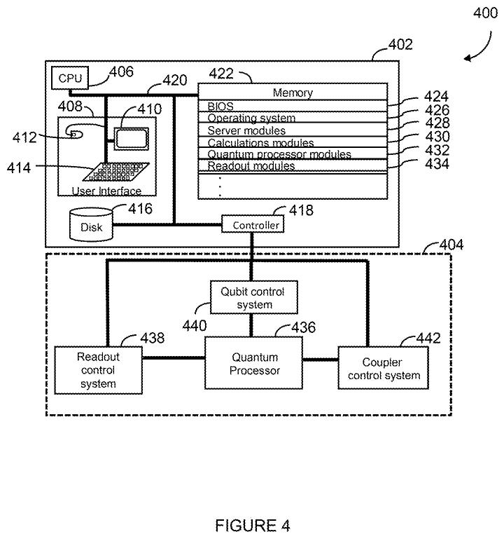

FIG. 4 shows a hybrid computing system 400 according to at least one exemplary implementation, including a digital computer 402 and a quantum computer 404, that may incorporate FMR technology as described above.

Digital computer 402 comprises a CPU 406, user interface elements 408, 410, 412 and 414, a disk 416, a controller 418, a bus 420 and a memory 422. Memory 422 comprises modules 424, 426, 428, 430, 432, and 434.

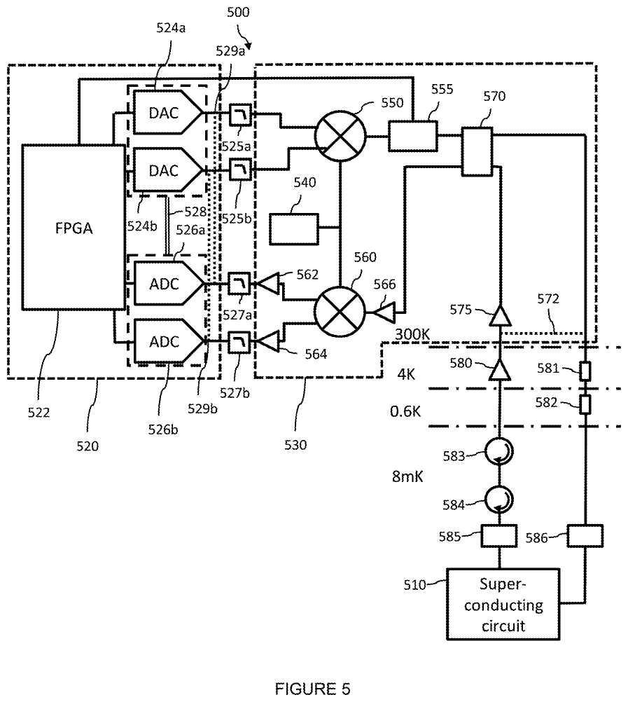

Quantum computer 404 comprises quantum processor 436, a readout control system 438, a qubit control system 440, and a coupler control system 442. Quantum computer 404 can incorporate FMR technology comprising superconducting resonators (such as superconducting resonator 300 of FIG. 3 described above). Quantum processor 436 can include multiple qubits (not shown in FIG. 4). FMR technology comprising superconducting resonators (such as superconducting resonator 300 of FIG. 3) can be used to read out states of at least some of the multiple qubits of quantum processor 436. Computing system 400 can comprise a readout system such as readout system 500 of FIG. 5 (described below).

### Readout System

FIG. 5 shows a readout system 500 for a superconducting circuit 510 according to at least one exemplary implementation. In the illustrated implementation of FIG. 5, superconducting circuit 510 comprises one or more superconducting resonators (not shown in FIG. 5) such as superconducting resonator 300 of FIG. 3. In one implementation, superconducting circuit 510 comprises a superconducting quantum processor. In another implementation, superconducting circuit 510 comprises a superconducting classical processor.

Readout system 500 comprises a digital board 520 and a microwave board 530. Digital board 520 comprises a Field Programmable Gate Array (FPGA) 522 (such as a Xilinx Kintex-7 FPGA from Xilinx, Inc. of San Jose, Calif., US), two Digital-to-Analog Converters (DACs) 524a and 524b, and two Analog-to-Digital Converters (ADCs) 526a and 526b. In some implementations, digital board 520 comprises two FPGAs, one providing output to DACs 524a and 524b, and the other providing output to ADCs 526a and 526b. In one implementation, each of DACs 524a and 524b can be implemented using an Analog Devices 9129 DAC which is a dual-channel 14-bit DAC operating at up to about 5.6 Gsps (Giga samples per second). ADCs 526a and 526b can be implemented using a multi-channel device such as an E2V EV10AQ190 which is a quad-channel 10-bit ADC capable of operating in dual-channel mode at up to about 2.5 Gsps.

Readout system 500 advantageously enables independent addressing of the two side-bands of the FMR spectrum. The complex received signal is given by:

x(n)=l(n)+jQ(n)

where l(n) is an output of ADC 526a and Q (n) is an output of ADC 526b.

An FMR spectrum can be computed as follows:

$${X}_{k} = \frac{1}{N} {\sum }_{n = 0}^{N - 1} x ( n ) [ cos ( \frac{2 π kn}{N} ) - j sin ( \frac{2 π kn + 2 π k τ}{N} ) ]$$

for kϵ0,1,2,3 . . . N−1. The second term in the argument of the sine function in the above expression for the FMR spectrum depends on τ, and can be used to compensate for a phase imbalance between the two mixer channels that can result from the analog nature of the mixer.

Digital board 520 further comprises two loopback lines 529a and 529b, and a sync/clock connection 528. Loopback line 529a connects an output of DAC 524a to an input of ADC 526a. Loopback line 529b connects an output of DAC 524b to an input of ADC 526b.

Microwave board 530 (also referred to in the present application as microwave subsystem 530) further comprises a loopback line 572. Loopback line 572 connects the input and output to a cryogenic subsystem (not shown in FIG. 5) used to cool superconducting device 510 to temperatures as low as a few mK (milli-Kelvin).

Loopback lines 529a and 529b on digital board 520, and loopback line 572 on microwave board 530 are optional, and used when required to bypass other elements of readout system 500.

Readout system 500 further comprises two reconstruction filters 525a and 525b, and two anti-aliasing filters 527a and 527b. Reconstruction filters 525a and 525b are low-pass analog filters that can be used to produce a band-limited analog signal from a digital input. Anti-aliasing filters 527a and 527b are low-pass analog filters that can be used to band-limit a received signal in order to satisfy or approximately satisfy a sampling theorem over a band of interest.

Microwave board 530 comprises a Voltage-Controlled Oscillator (VCO)/Phase Locked Loop (PLL) 540 which provides a reference microwave signal, mixers 550 and 560, and programmable attenuators 570. Microwave board 530 further comprises amplifiers 562, 564, 566, and 575. Amplifiers 562, 564, 566 and 575 can be used to provide level control on a signal received from superconducting circuit 510. In one implementation, amplifier 566 can be a Miteq AFS4-02000800-30-22P-4, and amplifier 575 can be a Miteq AFD3-040080-28-LN low-noise amplifier. These exemplary amplifiers are available from Miteq Inc., of Hauppauge, N.Y., US. Microwave board 530 further comprises a microwave switch 555 controlled by a signal from FPGA 522 on digital board 520.

In one implementation, mixers 550 and 560 are complex mixers.

The illustrated readout system 500 further comprises amplifier 580, attenuators 581 and 582, circulators 583 and 584, and DC blocks 585 and 586. DC blocks 585 and 586 are used as a thermal break on each of the input and output lines to superconducting circuit 510.

In one implementation, amplifier 580 can be an LNF-3611-28-04000800 low-noise cryogenic amplifier. Amplifier 580 and attenuator 581 can operate at 4 K (Kelvin). Attenuator 582 can operate at 0.6 K. Circulators 583 and 584, and DC blocks 585 and 586, can operate at 8 mK. In one implementation, cryogenic circulators 583 and 584 can each be implemented using a Quinstar CTH0408KC, and DC blocks 585 and 586 can each be implemented using an Aeroflex/Inmet 8039.

Using 60 resonators and a bandwidth of 2.5 GHz in an example implementation, a data rate of approximately 600 Mbps can be achieved for a shift register stage (SRS) operation time of 25 ns.

Readout system 500 of FIG. 5 is an example of a system that can include one or more parallel-plate capacitors fabricated according to the systems and methods of the present application.

In some implementations, one or more parallel-plate capacitors fabricated according to the systems and methods of the present application can be included in control circuitry, for example circuity that can control calibration or operation of a quantum processor.

In some implementations, one or more parallel-plate capacitors fabricated according to the systems and methods of the present application can be included in a superconducting processor or co-processor. For example, one or more parallel-plate capacitors fabricated according to the systems and methods of the present application can be included in a superconducting quantum processor, a Single Flux Quantum (SFQ) or Rapid Single Flux Quantum (RSFQ) processor and/or a classical superconducting processor. In some implementations of a classical superconducting processor, one or more parallel-plate capacitors fabricated according to the systems and methods of the present application can be included in a resistor-capacitor (RC) filter.

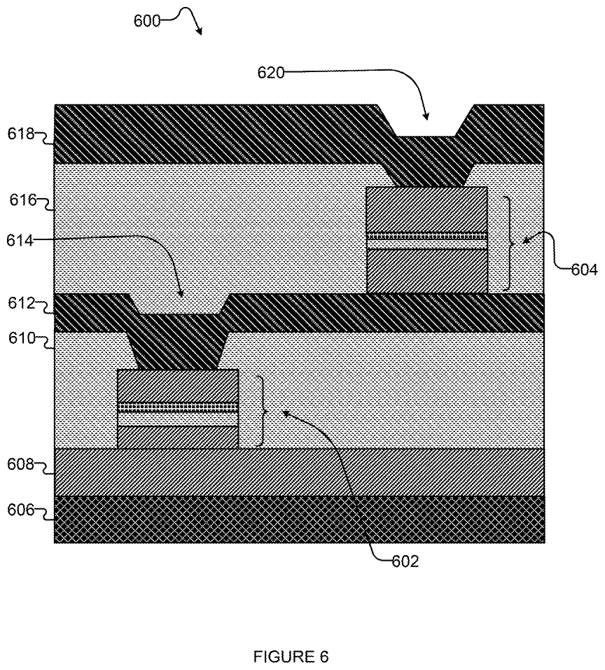

FIG. 6 is a sectional view of a portion of an exemplary superconducting integrated circuit 600 which includes a parallel-plate capacitor 602 and a Josephson junction 604, in accordance with the present systems and methods. Superconducting integrated circuit 600 further includes substrate 606, base electrode 608, interlayer dielectric 610, counter electrode 612 with via 614, interlayer dielectric 616, and superconducting metal wiring layer 618 with via 620. In some implementations, parallel-plate capacitor 602 is fabricated at a lower layer in the stack than Josephson junction 604 (as illustrated in the example implementation of FIG. 6). In some implementations, parallel-plate capacitor 602 is fabricated at a higher layer in the stack than Josephson junction 604.

The various embodiments and implementations described above can be combined to provide further embodiments and implementations. To the extent that they are not inconsistent with the specific teachings and definitions herein, all of the U.S. patents, U.S. patent application publications, U.S. patent applications, foreign patents, foreign patent applications and non-patent publications referred to in this specification and/or listed in the Application Data Sheet, including but not limited to the following: PCT Patent Application No. WO2016US31885 (published as International patent application publication WO2016183213A1), FREQUENCY MULTIPLEXED RESONATOR INPUT AND/OR OUTPUT FOR A SUPERCONDUCTING DEVICE, filed May 11, 2016; PCT Patent Application No. WO2018016237, SYSTEMS AND METHODS FOR FABRICATION OF SUPERCONDUCTING INTEGRATED CIRCUITS, filed Jan. 31, 2018; and U.S. Provisional Patent Application No. 62/636043, SYSTEMS AND METHODS FOR COUPLING A SUPERCONDUCTING TRANSMISSION LINE TO AN ARRAY OF RESONATORS, filed Feb. 27, 2018; and PCT Patent Application No. US2019/18792, SYSTEMS AND METHODS FOR COUPLING A SUPERCONDUCTING TRANSMISSION LINE TO AN ARRAY OF RESONATORS, filed Feb. 20, 2019, are incorporated herein by reference, in their entireties. Aspects of the embodiments can be modified, if necessary, to employ systems, circuits and concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of fabricating a parallel-plate capacitor in a superconducting integrated circuit, the method comprising:
forming a metal-oxide layer to overlie at least a portion of a first capacitor plate, the first capacitor plate comprising a material that is superconductive in a range of temperatures;
depositing a second capacitor plate to overlie at least a portion of the metal-oxide layer, the second capacitor plate comprising a material that is superconductive in a range of temperatures;
depositing a base electrode to overlie at least a portion of a substrate, the base electrode comprising a material that is superconductive in a range of temperatures;
depositing the first capacitor plate to overlie at least a portion of the base electrode, the first capacitor plate superconductingly electrically coupled to the base electrode; and
depositing a counter electrode to overlie at least a portion of the second capacitor plate, the counter electrode comprising a material that is superconductive in a range of temperatures, wherein the counter electrode is superconductingly electrically coupled to the second capacitor plate.

2. The method of claim 1, wherein depositing a base electrode to overlie at least a portion of a substrate includes depositing a base electrode by at least one of physical vapor deposition and chemical vapor deposition.

3. The method of claim 1, wherein depositing a base electrode to overlie at least a portion of a substrate includes depositing a base electrode to overlie a substrate that comprises silicon.

4. The method of claim 1, wherein depositing a base electrode to overlie at least a portion of a substrate includes depositing a superconducting metal layer that comprises at least one of niobium and aluminum.

5. The method of claim 1, wherein depositing a counter electrode to overlie at least a portion of the second capacitor plate includes depositing a counter electrode by at least one of physical vapor deposition and chemical vapor deposition.

6. The method of claim 1, wherein depositing a counter electrode to overlie at least a portion of the second capacitor plate includes depositing a counter electrode that comprises a superconducting trace.

7. The method of claim 1, wherein depositing a counter electrode to overlie at least a portion of a substrate includes depositing a superconducting metal layer that comprises at least one of niobium and aluminum.

8. The method of claim 1, further comprising patterning the first capacitor plate, the metal-oxide layer, and the second capacitor plate.

9. The method of claim 8, wherein patterning the first capacitor plate, the metal-oxide layer, and the second capacitor plate includes performing a photolithographic process that comprises masking and etching the first capacitor plate, the metal-oxide layer, and the second capacitor plate to remove at least a respective portion of each of the first capacitor plate, the metal-oxide layer, and the second capacitor plate.

10. The method of claim 1, wherein depositing a counter electrode to overlie at least a portion of the second capacitor plate includes:
depositing a dielectric layer to overlie at least a portion of the second capacitor plate and at least a portion of an exposed surface of the base electrode;
removing at least a portion of the dielectric layer to form a hole exposing at least a portion of the second capacitor plate; and
depositing a superconducting metal layer to at least partially fill the hole.

11. The method of claim 10, wherein depositing a dielectric layer to overlie at least a portion of the second capacitor plate includes depositing a dielectric layer that comprises silicon dioxide.

12. The method of claim 11, wherein depositing a dielectric layer to overlie at least a portion of the second capacitor plate includes planarizing the dielectric layer.

13. The method of claim 1, further comprising planarizing at least one of the base electrode, the first capacitor plate, the second capacitor plate, and the counter electrode.

14. The method of claim 1, wherein forming a metal-oxide layer to overlie at least a portion of the first capacitor plate includes depositing a metal-oxide layer to overlie at least a portion of the first capacitor plate.

15. The method of claim 14, wherein depositing a metal-oxide layer to overlie at least a portion of the first capacitor plate includes depositing a metal-oxide layer by at least one of physical vapor deposition and chemical vapor deposition.

16. The method of claim 14, wherein depositing a metal-oxide layer to overlie at least a portion of the first capacitor plate includes depositing a metal-oxide layer that comprises at least one of niobium oxide and aluminum oxide.

17. The method of claim 1, wherein forming a metal-oxide layer to overlie at least a portion of the first capacitor plate includes depositing a metal layer to overlie at least a portion of the first capacitor plate and oxidizing an exposed surface of the metal layer, the metal layer superconductive in a range of temperatures.

18. The method of claim 17, wherein depositing a metal layer to overlie at least a portion of the first capacitor plate includes depositing a metal layer by at least one of physical vapor deposition and chemical vapor deposition.

19. The method of claim 17, wherein depositing a metal layer to overlie at least a portion of the first capacitor plate includes depositing a metal layer that comprises at least one of niobium and aluminum.

20. The method of claim 17, wherein oxidizing an exposed surface of the metal layer includes exposing an exposed surface of the metal layer to oxygen gas (O2).

21. The method of claim 1, wherein a thickness of the first capacitor plate is in the range of 20 nm to 500 nm, a thickness of the metal-oxide layer is in the range of 2 nm to 20 nm, and a thickness of the second capacitor plate is in the range of 20 nm to 500 nm.

22. A superconducting integrated circuit comprising:
a substrate;
a base electrode overlying at least a portion of the substrate, the base electrode superconductive in a range of temperatures;
a parallel-plate capacitor overlying at least a portion of the base electrode, the parallel-plate capacitor comprising:
a first capacitor plate that is superconductive in a range of temperatures;
a metal-oxide layer overlying the first capacitor plate;
a second capacitor plate overlying the metal-oxide layer, the second capacitor plate superconductive in a range of temperatures, wherein the base electrode is superconductingly electrically coupled to the first capacitor plate.

23. The superconducting integrated circuit of claim 22, further comprising a superconducting metal layer overlying at least a portion of the first capacitor plate, wherein the metal-oxide layer includes a native metal oxide of the superconducting metal layer.

24. The superconducting integrated circuit of claim 22 further comprising:
a dielectric layer overlying at least a portion of the parallel-plate capacitor and at least an exposed portion of the base electrode;
a hole in the dielectric layer that exposes at least a portion of the second capacitor plate; and
a superconducting metal layer overlying at least a portion of the dielectric and at least a portion of the second capacitor plate, the superconducting metal layer which forms a superconducting via and a counter electrode, wherein the counter electrode is superconductingly electrically coupled to the second capacitor plate.

25. A quantum computer comprising the superconducting integrated circuit of claim 22.

26. The quantum computer of claim 25, wherein the superconducting integrated circuit further comprises a superconducting metal layer overlying at least a portion of the first capacitor plate, wherein the metal-oxide layer includes a native metal oxide of the superconducting metal layer.

27. The quantum computer of claim 25, wherein the superconducting integrated circuit further comprises:
a dielectric layer overlying at least a portion of the parallel-plate capacitor and at least an exposed portion of the base electrode;
a hole in the dielectric layer that exposes at least a portion of the second capacitor plate; and
a superconducting metal layer overlying at least a portion of the dielectric and at least a portion of the second capacitor plate, the superconducting metal layer which forms a superconducting via and a counter electrode, wherein the counter electrode is superconductingly electrically coupled to the second capacitor plate.
